(19) United States
(12) Patent Application Publication
(10) Pub. No.: US 2026/0096367 A1
(43) Pub. Date: Apr. 2, 2026

(54) METHODS FOR WET ATOMIC LAYER ETCHING OF TITANIUM NITRIDE USING HALOGENATION

(71) Applicant: Tokyo Electron Limited, Tokyo (JP)

(72) Inventors: Tulashi Dahal, Austin, TX (US); Kate Abel, Austin, TX (US)

(21) Appl. No.: 19/042,196

(22) Filed: Jan. 31, 2025

Related U.S. Application Data
(63) Continuation-in-part of application No. 18/900,795, filed on Sep. 29, 2024.

(51) Int. Cl. H01L 21/3213; C23F 1/30; H01L 21/02

(52) U.S. Cl. CPC H10P 50/667; C23F 1/30; H10P 70/27

(57) ABSTRACT

Various embodiments of methods are provided for etching titanium nitride (TiN) and other transition metal nitride materials in a wet ALE process. The methods disclosed herein use a wide variety of wet etch chemistries to: (a) halogenate a TiN surface and form a self-limiting, titanium halide or titanium oxyhalide passivation layer in a surface modification step of the wet ALE process, and (b) selectively remove the titanium halide or titanium oxyhalide passivation layer in a dissolution step of the wet ALE process. In the embodiments disclosed herein, a surface modification solution containing a halogenation agent dissolved in non-aqueous solvent is used to form a self-limiting, titanium halide or titanium oxyhalide passivation layer, which is selectively removed in an acidic dissolution solution via reactive dissolution.

### RELATED APPLICATIONS

This application is (1) a continuation-in-part (CIP) of commonly-assigned U.S. patent application Ser. No. 18/900,795, entitled “METHODS FOR WET ATOMIC LAYER ETCHING OF TUNGSTEN USING HALOGENATION,” filed Sep. 29, 2024, (2) and is related to commonly-assigned U.S. Pat. No. 11,802,342, entitled “METHOD FOR WET ATOMIC LAYER ETCHING OF RUTHENIUM,” filed Feb. 17, 2022, and U.S. patent application Ser. No. 18/542,181, entitled “METHODS FOR WET ATOMIC LAYER ETCHING OF TRANSITION METAL OXIDE DIELECTRIC MATERIALS,” filed Dec. 15, 2023; the disclosures of which are all expressly incorporated herein, in their entirety, by reference.

### BACKGROUND

This disclosure relates to semiconductor device manufacturing, and, in particular, to the removal and etching of polycrystalline materials, such as transition metal nitrides.

During routine semiconductor fabrication, various materials may be formed on a substrate and later removed by patterned etching, chemical-mechanical polishing and other techniques. A variety of techniques are known for etching layers on a substrate, including plasma-based etching (otherwise referred to as dry etching) and liquid-based etching (otherwise referred to as wet etching). Wet etching generally involves dispensing a chemical solution over the surface of a substrate or immersing the substrate in the chemical solution. The chemical solution often contains a solvent, chemicals designed to react with materials on the substrate surface and chemicals to promote dissolution of the reaction products. As a result of exposure of the substrate surface to the etchant, material is removed from the substrate. Etchant composition and temperature may be controlled to control the etch rate, specificity and residual material on the surface of the substrate post-etch.

Thermodynamics and kinetics both play roles in etchant formulation. The desired reactions need to be both thermodynamically and kinetically favorable for a successful etch. The requirements for success become much more stringent for etching polycrystalline materials. For these materials, it is desirable that the removal rates for each individual crystallite facet and grain boundary geometry is substantially similar regardless of crystallite morphology or environment. Surface roughness plays an important role in interface quality and electrical properties of nanoscale features. When etching nanoscale polycrystalline materials, differing etch rates at grain boundaries compared to the different crystal facets leads to roughening of the surface during etching. Further, it is desirable that the material removal rate should be uniform at the macroscopic and microscopic levels and occurs at a rate that is compatible with high volume manufacturing. Macroscopic uniformity can be addressed with careful engineering, but microscopic uniformity depends on the chemistry of the etch itself.

As geometries of substrate structures continue to shrink and the types of structures evolve, the challenges of etching substrates have increased. One technique that has been utilized to address these challenges is atomic layer etching (ALE). ALE is a process that removes thin layers sequentially through one or more self-limiting reactions. For example, ALE typically refers to techniques that can etch with atomic precision, i.e., by removing material one monolayer (or a few monolayers) of material at a time. ALE processes generally rely on a chemical modification of the surface to be etched followed by a selective removal of the modified layer. Thus, ALE processes offer improved performance by decoupling the etch process into sequential steps of surface modification and removal of the modified surface. In some embodiments, an ALE process may include multiple cyclic series of layer modification and etch steps, where the modification step modifies the exposed surfaces and the etch step selectively removes the modified layer. In such processes, a series of self-limiting reactions may occur and the cycle may be repeatedly performed until a desired or specified etch amount is achieved. In other embodiments, an ALE process may use just one cycle.

A variety of ALE processes are known, including plasma ALE, thermal ALE and wet ALE techniques. Like all ALE processes, wet ALE is typically a cyclic process that uses sequential, self-limiting reactions to selectively remove material from the surface. Unlike thermal and plasma ALE, however, the reactions used in wet ALE primarily take place in the liquid phase. Compared to other ALE processes, wet ALE is often desirable since it can be conducted at (or near) room temperature and atmospheric pressure. Additionally, the self-limiting nature of the wet ALE process leads to smoothing of the surface during etching rather than the roughening commonly seen during other etch processes.

A wet ALE process typically begins with a surface modification step, which exposes a material to a first solution to create a self-limiting modified surface layer. Ideally, the modified surface layer is confined to the top monolayer of the material and acts as a passivation layer to prevent the modification reaction from progressing any further. After the modified surface layer is formed, the wet ALE process may expose the modified surface layer to a second solution to selectively dissolve the modified surface layer in a subsequent dissolution step. The dissolution step must selectively dissolve the modified surface layer without removing any of the underlying unmodified material. This selectivity can be accomplished by using a different solvent in the dissolution step than was used in the surface modification step, changing the pH, or changing the concentration of other components in the first solvent. The wet ALE cycle can be repeated until a desired or specified etch amount is achieved.

Titanium nitride (TiN) is commonly used as a coating material, a gate electrode in complementary metal oxide semiconductor (CMOS) and a diffusion barrier in integrated circuits. Successful integration of TiN into CMOS and memory architecture requires process uniformity across length scales. Minimizing interface resistance is also important to improve device performance. One of the ways to minimize the interface resistance is to improve the surface smoothness at the interface between a TiN layer and an adjacent overlying layer. This is uniformity on the atomic length scale. Additionally, within-feature uniformity and within-wafer uniformity play important roles in device fabrication.

Conventional methods for etching TiN include thermal and plasma ALE processes. Thermal ALE processes require high temperatures and low pressure to modify the TiN surface and remove the modified surface layer. In thermal and plasma ALE processes, the surface modifying species are reactive gas(es), ions or radicals and the volatile product that forms during removal step is toxic. The TiN etch rate achieved in such processes is low and the post-etch morphology is rougher than the as-deposited TiN surface.

Accordingly, new methods of etching and new etch chemistries are needed for etching TiN and other transition metal nitride materials formed on a substrate.

### SUMMARY

The present disclosure provides improved wet etch processes and methods for etching transition metal nitride materials. More specifically, the present disclosure provides various embodiments of wet etch processes and methods that utilize new etch chemistries for etching transition metal nitride materials, such as titanium nitride (TiN), in a wet etch process.

As described in more detail below, the embodiments disclosed herein expose a transition metal nitride surface to a first etch solution to chemically modify the transition metal nitride surface and form a modified surface layer (otherwise referred to herein as a passivation layer), which is selectively dissolved in a second etch solution to etch the transition metal nitride surface. The first etch solution includes an electrophilic halogenation agent dissolved in a non-aqueous solvent. The electrophilic halogenation agent reacts with the transition metal nitride surface to halogenate and/or oxidize the transition metal nitride surface and form a transition metal halide or oxyhalide passivation layer, which is self-limiting and insoluble in the non-aqueous solvent.

A wide variety of etch chemistries can be used for halogenating and/or oxidizing an exposed transition metal nitride surface (such as, e.g., titanium nitride, TiN) and forming a self-limiting transition metal halide or oxyhalide passivation layer on the underlying transition metal nitride. In one example, the embodiments disclosed herein may use an electrophilic chlorinating agent to form a titanium chloride (TiClₓ) or titanium oxychloride (TiOCl₂) passivation layer on the underlying TiN surface. Alternatively, an electrophilic fluorinating agent or brominating agent may be used.

After forming a transition metal halide or oxyhalide passivation layer, a second etch solution may be dispensed onto the surface of the substrate to selectively dissolve the transition metal halide or oxyhalide passivation layer, thus removing the transition metal halide or oxyhalide passivation layer from the substrate surface without etching the unmodified transition metal nitride surface underlying the transition metal or oxyhalide halide passivation layer. Several etch chemistries can be used to selectively dissolve a titanium chloride (TiClₓ) or titanium oxychloride (TiOCl₂) passivation layer without dissolving the underlying TiN surface or increasing the post-etch surface roughness of the TiN surface. In some embodiments, the second etch solution may contain an acid, or a ligand and an acid.

The embodiments disclosed herein preserve the post-etch surface roughness of the transition metal nitride layer by forming a self-limiting transition metal halide or oxyhalide passivation layer, which is selectively removed via reactive dissolution (or ligand-assisted reactive dissolution) in the dissolution step. In some embodiments, the concentration of the electrophilic halogenation agent used in the first etch solution may be selected to adjust (e.g., increase or decrease) the etch rate of the transition metal nitride layer, while preserving or improving the post-etch surface roughness of the transition metal nitride layer. In some embodiments, the etch rate of the transition metal nitride layer may be increased by elevating the temperature of the first etch solution and/or the second etch solution above room temperature.

According to one embodiment, a method is provided herein for etching a substrate having a titanium nitride (TiN) layer. In some embodiments, the method may begin by receiving a substrate having a titanium nitride (TiN) layer, where a TiN surface is exposed on a surface of the substrate, and exposing the surface of the substrate to a surface modification solution comprising an electrophilic halogenation agent dissolved in a non-aqueous solvent. The electrophilic halogenation agent reacts with the TiN surface to form a titanium halide or titanium oxyhalide passivation layer, which is self-limiting and insoluble in the surface modification solution. The method further includes removing the surface modification solution from the surface of the substrate subsequent to forming the titanium halide or titanium oxyhalide passivation layer, and exposing the surface of the substrate to a dissolution solution to selectively remove the titanium halide or titanium oxyhalide passivation layer. The dissolution solution reacts with the titanium halide or titanium oxyhalide passivation layer to form soluble species, which are dissolved by the dissolution solution to expose an unmodified TiN surface underlying the titanium halide or titanium oxyhalide passivation layer. The method further includes removing the dissolution solution and the soluble species from the surface of the substrate to etch the TiN layer. In some embodiments, the steps of exposing the surface of the substrate to the surface modification solution, removing the surface modification solution, exposing the surface of the substrate to the dissolution solution, and removing the dissolution solution and the soluble species may be repeated a number of times until a predetermined amount of the TiN layer is removed from the substrate.

A wide variety of electrophilic halogenation agents and non-aqueous solvents may be used in the surface modification solution to form the titanium halide or titanium oxyhalide passivation layer. For example, the electrophilic halogenation agent may be an electrophilic chlorinating agent, an electrophilic fluorinating agent or an electrophilic brominating agent. Examples of electrophilic chlorinating agents that may be included within the surface modification solution include, but are not limited to, trichloroisocyanuric acid (TCCA), thionyl chloride, sulfuryl chloride, N-chlorosuccinimide, 1-chlorobenzotriazole, Chloramine-T and tert-butyl-N-chlorocyanamide. Examples of electrophilic fluorinating agents include, but are not limited to, Selectfluor™ (1-chloromethyl-4-fluoro-1,4-diazoniabicyclo[2.2.2]octane bis(tetrafluoroborate)), 1-fluoropyridinium triflate, 1-fluoro-2,4,6-trimethylpyridinium tetrafluoroborate, N-fluorobenzenesulfonimide, fluoroxytrifluoromethane, perchloryl fluoride, xenon difluoride and N-fluorobis[(trifluoromethyl)sulfonyl]imide. Examples of electrophilic brominating agents include, but are not limited to, N-bromosuccinimide, dibromoisocyanuric acid, tribromocyanuric acid, 1,3-Dibromo-5,5-Dimethylhydantoin and N-Bromoacetamide. The non-aqueous solvent may be an ether, a ketone, a halocarbon, a heterocyclic, an alcohol or another polar organic solvent or chlorocarbon solvent. For example, the non-aqueous solvent may be ethyl acetate, acetone, acetonitrile, dimethyl sulfoxide (DMSO), furan, dimethylformamide, methanol, diethyl ether, isopropyl alcohol, dioxane or toluene.

In one example, the surface modification solution may comprise trichloroisocyanuric acid (TCCA) dissolved in a polar organic solvent, such as ethyl acetate or acetone. When an electrophilic chlorinating agent is used, the electrophilic chlorinating agent may react with the TiN surface to form a titanium chloride (TiClₓ) or titanium oxychloride (TiOCl₂) passivation layer, which is self-limiting and insoluble in the surface modification solution.

In some embodiments, the concentration of the electrophilic chlorinating agent may be selected to adjust the etch rate of the TiN layer while preserving post-etch surface roughness. When TCCA is used, the concentration of TCCA used in the surface modification solution may range between 0.1% and 10% with higher TCCA concentration levels providing faster etch rates. In some embodiments, the concentration of TCCA used in the surface modification solution may range between 2% and 5%. Within this concentration range, the post-etch surface roughness is preserved and may even be improved compared to the initial surface roughness of the as-deposited TiN layer. In one example embodiment, a surface modification solution comprising 2% TCCA dissolved in ethyl acetate may provide a TiN etch rate of approximately 0.84 nm/cycle, while improving the post-etch surface roughness (RMS roughness ˜(0.72±0.02) nm) compared to the initial surface roughness of the as-deposited TiN layer (RMS roughness ˜(1.39±0.06) nm). Using 5% TCCA dissolved in ethyl acetate to modify the TiN surface results in a faster TiN etch rate, but higher post-etch surface roughness, compared to the 2% TCCA-EA surface modification solution. Thus, the 2% TCCA-EA surface modification solution may be preferred, in some embodiments, to minimize the post-etch surface roughness while maintaining an acceptable TiN etch rate.

In some embodiments, the etch rate of the TiN layer may be additionally or alternatively adjusted by adjusting the temperature of the surface modification solution to alter the solution phase kinetics of the surface modification step. In one example, the surface modification step may be performed at (or near) room temperature (e.g., approximately 20-24° C.). In another example, the temperature of the surface modification solution may be elevated above room temperature (e.g., approximately 25-100° C.) to increase the rate of chlorination and the etch rate of the TiN layer. However, the temperature of the surface modification solution may generally depend on the non-aqueous solvent used in the surface modification solution. For example, the surface of the substrate may be exposed to the surface modification solution at an elevated temperature ranging between 25° C. and 65° C. when ethyl acetate is used in the surface modification solution. Increasing the temperature of the surface modification solution increases the etch rate of the TiN layer by increasing a chlorination rate of the TiN surface and/or the thickness of the titanium chloride or titanium oxychloride passivation layer formed thereon. In some embodiments, the temperature of the surface modification solution may include the entire liquid range of the solvent used. For example, the temperature of the surface modification solution may range between approximately: (a) −83° C. to 77° C. for ethyl acetate, (b) −95° C. to 56° C. for acetone, (c) 19° C. to 189° C. for DMSO, etc.

In some embodiments, the dissolution solution may be an aqueous or non-aqueous solution containing an acid. For example, the dissolution solution may contain: (a) an acid, or (b) an acid dissolved in water. Examples of acids that may be included within the dissolution solution include, but are not limited to, sulfuric acid (H₂SO₄), hydrochloric acid (HCl), hydrofluoric acid (HF) and nitric acid (HNO₃). The acid within the dissolution solution reacts with the titanium halide or titanium oxyhalide passivation layer to form soluble species, which are selectively dissolved by the dissolution solution to expose the unmodified TiN surface underlying the titanium halide or titanium oxyhalide passivation layer. In one example embodiment, the dissolution solution may be an acidic solution comprising 0.05 mM to 5 M of sulfuric acid (H₂SO₄).

In some embodiments, the dissolution temperature may be elevated above room temperature to increase the rate of dissolution and the etch rate of the TiN layer. For example, the surface of the substrate may be exposed to the dissolution solution at an elevated temperature (ranging, e.g., between 25° C. and 100° C. for aqueous dissolution solutions) to increase the etch rate of the TiN layer by increasing a dissolution rate of the titanium halide or titanium oxyhalide passivation layer.

In some embodiments, a ligand may be added to the dissolution solution to assist in the selective dissolution of the titanium halide or titanium oxyhalide passivation layer and/or increase the dissolution rate of the titanium halide or titanium oxyhalide passivation layer. The ligand added to the dissolution solution may be a complexing agent, a chelating agent or a reducing agent. Examples of ligands that can be added to the dissolution solution include, but are not limited to, catechol, cupferron and oxalic acid. However, other ligands can also be used to assist in the selective dissolution of the titanium halide or titanium oxyhalide passivation layer. For example, carboxylic acids (such as, e.g., oxalic acid, formic acid, acetic acid, etc.), amine-containing ligands (such as, e.g., cupferron, ethylenediamine, ethylenediaminetetraacetic acid (EDTA), iminodiacetic acid, etc.), ascorbate anion-containing ligands (such as, e.g., ascorbic acid, sodium ascorbate, calcium ascorbate or potassium ascorbate, etc.) and other molecules that bind to the titanium metal surface through N, P, O, or S heteroatoms can be used as a ligand.

According to another embodiment, a method is provided herein for etching a substrate using a wet atomic layer etching (ALE) process. In some embodiments, the method may begin by receiving the substrate, the substrate having a titanium nitride (TiN) layer, wherein a TiN surface is exposed on a surface of the substrate. The method further includes selectively etching the TiN layer by performing multiple cycles of the wet ALE process, wherein each cycle comprises: (a) exposing the TiN surface to a first etch solution comprising an electrophilic chlorinating agent in a non-aqueous solvent to form a chemically modified TiN surface layer that is self-limiting and insoluble in the non-aqueous solvent; (b) rinsing the substrate with a first purge solution to remove the first etch solution from the surface of the substrate; (c) exposing the chemically modified TiN surface layer to a second etch solution to selectively dissolve the chemically modified TiN surface layer expose an unmodified TiN surface underlying the chemically modified TiN surface layer; and (d) rinsing the substrate with a second purge solution to remove the second etch solution from the surface of the substrate and etch the TiN layer.

A wide variety of electrophilic chlorinating agents and non-aqueous solvents may be used in the first etch solution to form the chemically modified TiN surface layer. In one embodiment, the first etch solution may include trichloroisocyanuric acid (TCCA) dissolved in a polar organic solvent, such as ethyl acetate or acetone. However, other electrophilic chlorinating agents and non-aqueous solvents may be used in the first etch solution, as discussed above. When an electrophilic chlorinating agent is used within the first etch solution, the electrophilic chlorinating agent may react with the TiN surface to form a titanium chloride (TiClₓ) or titanium oxychloride (TiOCl₂) passivation layer, which is self-limiting and insoluble in the non-aqueous solvent.

In some embodiments, the concentration of the electrophilic chlorinating agent used in the first etch solution may be selected to adjust the etch rate of the TiN layer without increasing the post-etch surface roughness of the TiN layer compared to the initial surface roughness of the TiN layer before etching. When TCCA is used, a concentration of TCCA in the surface modification solution may range between 0.1% and 10% with higher TCCA concentration levels providing faster etch rates. In some embodiments, the concentration of TCCA used in the first etch solution may range between 2% and 5% to provide a desired etch rate while preserving (or even improving) the post-etch surface roughness of the TiN layer. In one example embodiment, the surface modification solution may comprise 2% TCCA dissolved in ethyl acetate or acetone.

In some embodiments, an acid may be used in the second etch solution to selectively dissolve the chemically modified TiN surface layer (such as, e.g., a titanium chloride or titanium oxychloride passivation layer). The acid may react with the chemically modified TiN surface layer to selectively dissolve the chemically modified TiN surface layer and expose the unmodified TiN surface underlying the chemically modified TiN surface layer. In some embodiments, the dissolution solution may further include a ligand. The ligand may be added to the dissolution to assist in the selective dissolution of the titanium halide or titanium oxyhalide passivation layer and/or increase the dissolution rate.

A wide variety of ligands and acids may be used in the second etch solution to selectively dissolve the chemically modified TiN surface layer without increasing the post-etch surface roughness of the TiN layer. For example, the acid may be sulfuric acid (H₂SO₄), hydrochloric acid (HCl), hydrofluoric acid (HF) or nitric acid (HNO₃). Examples of ligands that may be added to the acid include, but are not limited to, oxalic acid, formic acid, acetic acid, cupferron, ethylenediamine, ethylenediaminetetraacetic acid (EDTA), iminodiacetic acid, catechol, ascorbic acid, sodium ascorbate, calcium ascorbate and potassium ascorbate. In one example implementation, the dissolution solution may be an acidic solution comprising 0.05 mM to 5 M of sulfuric acid (H₂SO₄).

In some embodiments, the substrate may further include an oxide layer, wherein an oxide surface of the oxide layer is exposed on the surface of the substrate. For example, the oxide layer may be zirconium dioxide (ZrO₂), hafnium dioxide (HfO₂) or hafnium zirconium dioxide (HfₓZr₍₁₋ₓ₎O₂). In such embodiments, the step of selectively etching the TiN layer may be selective to the oxide layer.

As noted above and described further herein, the present disclosure provides various embodiments of methods that utilize new etch chemistries for etching a transition metal nitride layer in a wet etch process. Specifically, methods and new etch chemistries are provided herein for etching titanium nitride (TiN) in a wet ALE process. Of course, the order of discussion of the different steps as described herein has been presented for the sake of clarity. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this Summary Section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 is a flowchart diagram illustrating one embodiment of a method that utilizes the techniques disclosed herein for etching a substrate having a titanium nitride (TiN) surface exposed on a surface of the substrate.

FIG. 2 illustrates one example of a cyclic wet ALE process that can be used to etch a transition metal nitride surface, such as a TiN surface, in accordance with a first embodiment of the present disclosure.

FIG. 3 is a graph depicting exemplary etch amounts (expressed in nanometers, nm) that may be achieved over time (expressed in minutes, min) when etching a TiN surface using various etch chemistries.

FIG. 4 is a graph depicting exemplary etch rates (expressed in nm/cycle) achieved as a function of trichloroisocyanuric acid (TCCA) concentration (expressed %) when etching a TiN surface using various concentrations of TCCA dissolved in ethyl acetate in the surface modification solution and 1 M of sulfuric acid (H₂SO₄) in the dissolution solution.

FIG. 5A is a graph depicting the X-ray photoelectron spectroscopy (XPS) spectra for the titanium (Ti) 2p peak before and after exposing the TiN surface to two different TCCA-EA solutions (e.g., 2% TCCA in EA and 5% TCCA in EA).

FIG. 5B is a graph depicting the XPS spectra of the chlorine (Cl) 2p peak before and after exposing the TiN surface to the two different TCCA-EA solutions.

FIG. 5C is a graph depicting the XPS spectra of the nitrogen (N) 1s peak before and after exposing the TiN surface to the two different TCCA-EA solutions.

FIG. 5D is a graph depicting the XPS spectra of the oxygen (O) 1s peak before and after exposing the TiN surface to the two different TCCA-EA solutions.

FIG. 6 is a graph depicting root mean square (RMS) roughness (expressed in nm) of an as-deposited TiN surface and post-etch TiN surfaces as a function of etch amount (expressed in nm) for the two different TCCA-EA solutions.

FIG. 7 is a graph depicting exemplary etch amounts (expressed in nm) and etch rates (expressed in nm/cycle) achieved as a function of cycle (expressed in cycle number) when etching titanium nitride (TiN) and hafnium dioxide (HfO₂) surfaces using 2% TCCA dissolved in ethyl acetate in the surface modification solution and 1 M of sulfuric acid (H₂SO₄) in the dissolution solution at different temperatures (e.g., 50° C. and 60° C.).

FIG. 8 is a flowchart diagram illustrating one embodiment of a method that utilizes the techniques disclosed herein for etching a substrate having a TiN surface exposed on a surface of the substrate using a cyclic wet atomic layer etching (ALE) process.

FIG. 9 is a block diagram illustrating one embodiment of a processing system that can be used to etch a transition metal nitride surface, such as a TiN surface, using the wet ALE processes disclosed herein.

### DETAILED DESCRIPTION

Wet atomic layer etching (ALE) processes can be used to etch transition metals (and other materials) formed on a substrate by performing one or more cycles of the wet ALE process, where each cycle includes a surface modification step and a dissolution step. In the surface modification step, an exposed surface of the transition metal may be exposed to a surface modification solution to chemically modify the exposed surface of the transition metal and form a modified surface layer. In the dissolution step, the modified surface layer is selectively removed by exposing the modified surface layer to a dissolution solution to dissolve the modified surface layer and exposed an unmodified surface of the transition metal. Purge steps are performed between the surface modification and dissolution steps to prevent the surface modification and dissolution solutions from mixing, and the process may be repeated in a cyclic manner until a desired amount of etching is achieved. In order to achieve atomic layer etching, however, at least one of the surface modification and dissolutions steps must be self-limiting.

A variety of transition metals have been etched using wet ALE processes, including cobalt (Co), ruthenium (Ru), copper (Cu), gold (Au), platinum (Pt), Iridium (Ir), molybdenum (Mo), tungsten (W), etc. Wet ALE processes for etching such transition metals are disclosed in various commonly-assigned patents and applications, including U.S. Pat. No. 10,982,335, entitled “Wet Atomic Layer Etching Using Self-Limiting and Solubility-limited Reactions,” U.S. Pat. No. 11,802,342, entitled “Methods for Wet Atomic Layer Etching of Ruthenium,” U.S. Pat. No. 11,866,831, entitled “Methods for Wet Atomic Layer Etching of Copper,” U.S. Patent Application Publication No. 2023/0121246, entitled “Methods for Wet Atomic Layer Etching of Noble Metals,” U.S. patent application Ser. No. 18/240,142, entitled “Methods for Wet Atomic Layer Etching of Molybdenum,” U.S. patent application Ser. No. 18/619,491, entitled “Methods for Wet Atomic Layer Etching of Tungsten,” U.S. patent application Ser. No. 18/636,818, entitled “Methods for Wet Atomic Layer Etching of Molybdenum in Aqueous Solution,” U.S. patent application Ser. No. 18/900,795, entitled “Methods for Wet Atomic Layer Etching of Tungsten Using Halogenation,” each of which is incorporated herein by reference.

Wet ALE processes have also been used to etch transition metal oxide dielectrics such as, e.g., zirconium dioxide (ZrO₂), hafnium dioxide (HfO₂) and hafnium zirconium dioxide (HfₓZr₍₁₋ₓ₎O₂) dielectrics. Commonly assigned U.S. patent application Ser. No. 18/542,181, entitled “Methods for Wet Atomic Layer Etching of Transition Metal Oxide Dielectric Materials,” discloses various wet ALE processes and methods for etching transition metal oxide dielectric materials.

In some of the previously disclosed wet ALE methods, halogenation is used in the surface modification step—instead of oxidation—to chemically modify an exposed surface of a transition metal layer (such as, e.g., a ruthenium or tungsten layer) or a transition metal oxide layer (such as, e.g., a ZrO₂ or HfO₂ layer) and form a transition metal halide or oxyhalide passivation layer, which is selectively removed in a subsequent dissolution step to etch the transition metal layer or transition metal oxide layer. Through extensive research and experimentation, the present inventors recognized that similar etch chemistry can be used to etch a transition metal nitride layer in a wet ALE process.

Titanium nitride (TiN) is one example of a transition metal nitride layer that is commonly used in various integrated circuits. As noted above, TiN is typically etched using a thermal ALE process or a plasma-based etch process, such as reactive ion etching (RIE). These etch processes have several disadvantages. For example, thermal ALE requires the surface modification and removal steps to be performed at high temperatures (e.g., 150-350° C.) and low pressure (e.g., about 1 Torr), which requires significant power consumption. In one example thermal ALE process, a TiN surface may be exposed to a strong gas-phase oxidant (such as ozone, O₃) at high temperature and low pressure to form a titanium oxide (TiO₂) surface layer on the TiN surface. The TiO₂ surface layer may be subsequently removed by exposing the modified surface to a gas-phase fluorinating agent (such as hydrogen fluoride, HF), which reacts with the TiO₂ surface layer to form titanium tetrafluoride (TiF₄) and water (H₂O) as reaction by-products. In the thermal ALE process described above, the volatile reaction product (TiF₄) formed during the removal step is toxic and the post-etch surface roughness is typically higher than the starting surface. RIE, on the other hand, is an anisotropic etch process that uses reactant gases to form a modified surface layer on a TiN surface and high energy ions to remove the modified surface layer from the TiN surface. This anisotropic process often leads to undercutting and damage to the underlying layers.

In contrast to conventional thermal and plasma-based etch processes, wet ALE is an isotropic process that can be achieved at (or near) room temperature and ambient pressure. As noted above, wet ALE utilizes a first etch solution (e.g., a surface modification solution) to form a conformal modified surface layer on an exposed substrate surface that can be selectively removed by a second etch solution (e.g., a dissolution solution) to preserve, or even improve, the post-etch surface morphology. The self-limiting nature of the wet ALE process can also improve the etch behavior in high aspect ratio features by eliminating depth-loading effects.

The present disclosure provides a new wet ALE process for etching a transition metal nitride layer formed on a substrate. More specifically, the present disclosure provides various embodiments of methods that utilize new etch chemistries for etching titanium nitride (TiN) in a wet ALE process. As described in more detail below, the wet ALE processes and methods disclosed herein use an electrophilic halogenation agent to halogenate and/or oxidize a TiN surface exposed on a substrate and form a self-limiting, titanium halide or titanium oxyhalide passivation layer on the underlying TiN surface in a surface modification step of the wet ALE process. The titanium halide or titanium oxyhalide passivation layer is then selectively removed in a subsequent dissolution step of the wet ALE process to etch the TiN surface at the atomic scale. In the wet ALE processes and methods disclosed herein, the concentration of the electrophilic halogenation agent used in the surface modification solution may be selected to adjust the etch rate of the TiN layer without substantially increasing the post-etch surface roughness of the TiN surface. Alternatively, the etch rate of the TiN layer may be adjusted by increasing (or decreasing) the temperature of the wet etch chemistry.

Unlike conventional methods for etching TiN, the methods disclosed herein utilize new etch chemistries for etching TiN in a wet ALE process that provides self-limiting behavior in the surface modification and dissolution steps. As used herein, a “self-limiting” behavior, or “self-limiting” reaction, is one in which the reaction rate goes to zero over time. In comparison to a strictly self-limiting reaction, a “quasi-self-limiting” reaction is one in which the reaction rate decreases over time but does not go to zero. In the wet ALE processes and methods disclosed herein, self-limiting behavior is provided in the surface modification step by using an electrophilic halogenating agent (such as, e.g., TCCA) in non-aqueous solvent to form a titanium halide or titanium oxyhalide passivation layer (such as, e.g., a titanium chloride or titanium oxychloride passivation layer) that is insoluble in the non-aqueous solvent. In addition to self-limiting surface modification, the wet ALE processes and methods disclosed herein may provide self-limiting behavior in the dissolution step by using reactive dissolution (or ligand-assisted reactive dissolution) to selectively remove the titanium halide or titanium oxyhalide passivation layer.

The techniques disclosed herein may be performed on a wide variety of substrates having a wide variety of layers and features formed thereon. In general, the substrates utilized with the techniques disclosed herein may be any substrates for which the etching of material is desirable. For example, the substrate may be a semiconductor substrate having one or more semiconductor processing layers (all of which together may comprise the substrate) formed thereon. In one embodiment, the substrate may be a substrate that has been subject to multiple semiconductor processing steps which yield a wide variety of structures and layers, all of which are known in the substrate processing art. In one embodiment, the substrate may be a semiconductor wafer including the various structures and layers formed.

The techniques disclosed herein may be used to etch a wide variety of materials, including polycrystalline materials, single-crystalline materials and amorphous materials. In some embodiments, the techniques described herein may be used to etch a transition metal nitride material. In one exemplary embodiment, the material to be etched may be titanium nitride (TiN). Although the techniques described herein are discussed below in reference to etching TiN, it will be recognized by those skilled in the art that such an example is merely exemplary and the techniques described herein may be used to etch other transition metal nitride materials such as, for example, molybdenum nitride (MoN), tantalum nitride (TaN), chromium nitride (CrN), aluminum nitride (AlN), hafnium nitride (HfN), zirconium nitride (ZrN) and iron nitride (FeₓN).

The techniques disclosed herein offer multiple advantages over other etch techniques used for etching transition metal nitrides. For example, the techniques disclosed herein provide the benefits of ALE, such as precise control of total etch amount, control of surface roughness, and improvements in wafer-scale uniformity. The techniques disclosed herein also provide various benefits of wet etching, such as the simplicity of the etch chamber, self-limiting reactions at near atmospheric temperature and pressure etching conditions, and reduced surface roughness. Unlike conventional etch processes used to etch transition metal nitrides, such as TiN, the techniques disclosed herein provide a wet ALE process that provides a self-limiting surface modification step and a selective dissolution step for etching the transition metal nitride surface. As such, the techniques described herein provide unique methods for etching TiN and other transition metal nitrides.

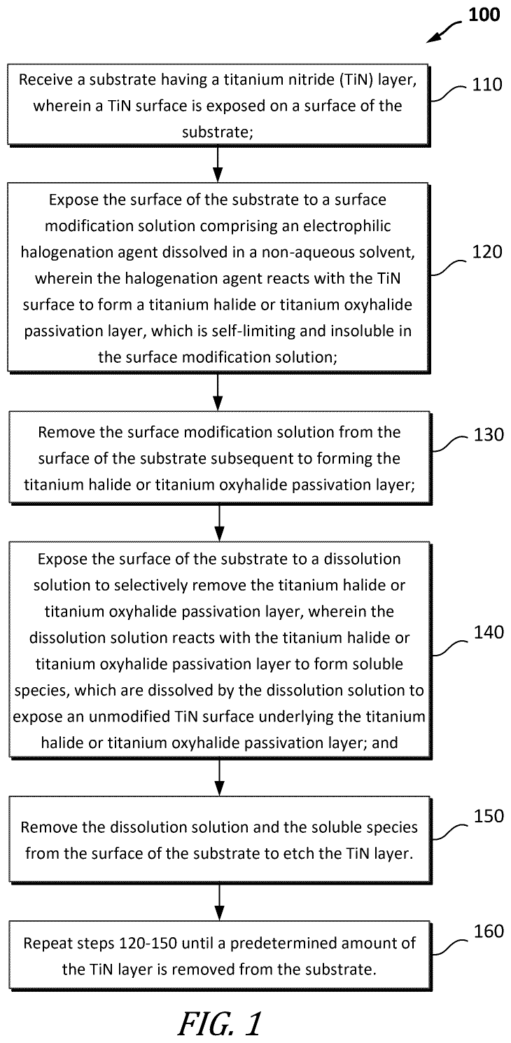

FIG. 1 illustrates one embodiment of a method 100 that can be used to etch a substrate using a wet atomic layer etching (ALE) process. More specifically, FIG. 1 illustrates an embodiment of a method 100 that can be used to etch a titanium nitride (TiN) layer formed on a substrate using a wet ALE process. It will be recognized that the embodiment of FIG. 1 is merely exemplary and additional methods may utilize the wet ALE techniques described herein. Further, additional processing steps may be added to the method shown in the FIG. 1 as the steps described are not intended to be exclusive. Moreover, the order of the steps is not limited to the order shown in the figures as different orders may occur and/or various steps may be performed in combination or at the same time.

The method 100 shown in FIG. 1 includes receiving a substrate having a titanium nitride (TiN) layer, wherein a TiN surface is exposed on a surface of the substrate (in step 110), and exposing the surface of the substrate to a surface modification solution comprising an electrophilic halogenation agent dissolved in a non-aqueous solvent (in step 120). The electrophilic halogenation agent included within the surface modification solution reacts with the TiN surface to form a titanium halide or titanium oxyhalide passivation layer, which is self-limiting and insoluble in the surface modification solution. A wide variety of electrophilic halogenation agents may be included within the surface modification solution, as described in more detail below.

After forming the self-limiting titanium halide or titanium oxyhalide passivation layer, method 100 removes the surface modification solution from the surface of the substrate (in step 130), and exposes the surface of the substrate to a dissolution solution to selectively remove the titanium halide or titanium oxyhalide passivation layer (in step 140). The dissolution solution reacts with the titanium halide or titanium oxyhalide passivation layer to form soluble species, which are dissolved by the dissolution solution to expose an unmodified TiN surface underlying the titanium halide or titanium oxyhalide passivation layer. The method 100 removes the dissolution solution and the soluble species from the surface of the substrate to etch the TiN layer (in step 150). In some embodiments, the method may repeat steps 120-150 a number of times (in step 160) until a predetermined amount of the TiN layer is removed from the substrate.

The method 100 shown in FIG. 1 can be used to etch TiN (and other transition metal nitrides) in a wet ALE process by performing multiple cycles of the wet ALE process, wherein each cycle includes a surface modification step (step 120) to halogenate and/or oxidize the TiN surface and form a titanium halide or titanium oxyhalide passivation layer, and a dissolution step (step 140) to selectively remove the titanium halide or titanium oxyhalide passivation layer without removing the unmodified TiN surface underlying the titanium halide or titanium oxyhalide passivation layer. Purge steps (steps 130 and 150) are performed between the surface modification and dissolution steps to prevent the surface modification and dissolution solutions from mixing, and the process may be repeated in a cyclic manner until a desired amount of etching is achieved. Example etch chemistries that may be used in the surface modification step (step 120), the dissolution step (step 140) and the purge steps (steps 130 and 150) are described in more detail below.

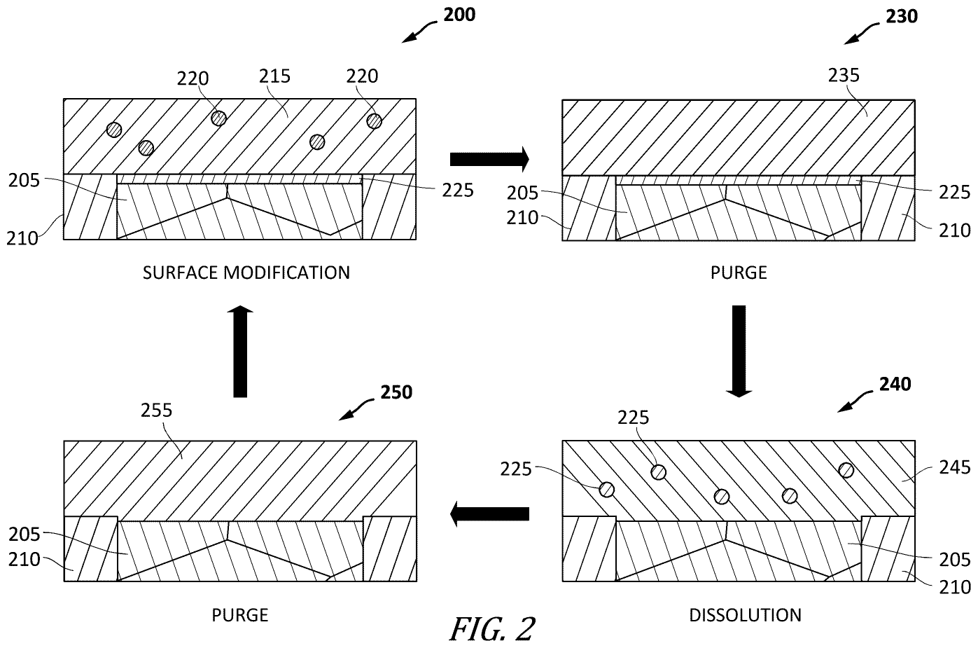

FIG. 2 illustrates one example of a wet ALE process that can be used to etch TiN (and other transition metal nitrides) in accordance with a first embodiment of the present disclosure. As described in more detail below, the wet ALE process shown in FIG. 2 is a cyclical process consisting of one or more ALE cycles, where each ALE cycle includes a surface modification step 200, a first purge step 230, a dissolution step 240 and a second purge step 250.

In the wet ALE process shown in FIG. 2, a TiN layer 205 surrounded by a dielectric material 210 is brought in contact with a surface modification solution 215 during the surface modification step 200. The surface modification solution 215 is a non-aqueous solution containing an electrophilic halogenation agent 220 dissolved in non-aqueous solvent. The electrophilic halogenation agent 220 reacts with an exposed surface of the TiN layer 205 to halogenate and/or oxidize the TiN surface and form a titanium halide or titanium oxyhalide passivation layer 225, which is self-limiting and insoluble in the non-aqueous solvent. The dielectric material 210 may include a wide variety of dielectric materials. In some embodiments, the dielectric material 210 may be a transition metal oxide material such as, e.g., a zirconium dioxide (ZrO₂), hafnium dioxide (HfO₂) or hafnium zirconium dioxide (HfₓZr₍₁₋ₓ₎O₂) dielectric. As described in more detail below, the surface modification solution 215 used during the surface modification step 200 may chemically modify the TiN surface and form a titanium halide or titanium oxyhalide passivation layer 225 thereon without modifying exposed surfaces of the dielectric material 210.

A wide variety of electrophilic halogenation agents 220 and non-aqueous solvents may be used in the surface modification solution 215. For example, the electrophilic halogenation agent 220 may be an electrophilic chlorinating agent, an electrophilic fluorinating agent, or an electrophilic brominating agent. The non-aqueous solvent may be an ether, a ketone, a halocarbon, a heterocyclic, an alcohol or another polar organic solvent or chlorocarbon solvent. In one example embodiment, the surface modification solution 215 may contain trichloroisocyanuric acid (TCCA) dissolved in ethyl acetate or acetone. However, other electrophilic halogenation agents and non-aqueous solvents may also be used in the surface modification solution 215, as described in more detail below.

After forming the titanium halide or titanium oxyhalide passivation layer 225 in the surface modification step 200, the first purge step 230 is performed to remove the surface modification solution 215 from the surface of the substrate. In the first purge step 230, the substrate is rinsed with a first purge solution 235 to remove the surface modification solution 215 and excess reactants from the surface of the substrate. The first purge solution 235 should not react with the titanium halide or titanium oxyhalide passivation layer 225 formed during the surface modification step 200, or with the reactants in the surface modification solution 215. In some embodiments, the first purge solution 235 may use the same solvent (e.g., ethyl acetate or acetone) used in the surface modification solution 215. However, other solvents may also be utilized, as discussed in more detail below. In some embodiments, the first purge step 230 may be long enough to completely remove all excess reactants from the substrate surface.

After the substrate is rinsed, the dissolution step 240 is performed to selectively remove the titanium halide or titanium oxyhalide passivation layer 225 formed during the surface modification step 200. In the dissolution step 240, the substrate is exposed to a dissolution solution 245 to selectively remove or dissolve the titanium halide or titanium oxyhalide passivation layer 225 without removing the unmodified TiN layer 205 underlying titanium halide or titanium oxyhalide passivation layer 225 or the dielectric material 210 surrounding the TiN layer 205.

The dissolution solution 245 may be an aqueous or non-aqueous solution containing: (a) an acid, or (b) an acid dissolved in water. When the titanium halide or titanium oxyhalide passivation layer 225 is exposed to the dissolution solution 245, the acid within the dissolution solution 245 reacts with the titanium halide or titanium oxyhalide passivation layer 225 to form the soluble species, which are dissolved by the dissolution solution 245 to expose the unmodified TiN layer 205 underlying the titanium halide or titanium oxyhalide passivation layer 225. Examples of acids that may be included within the dissolution solution 245 include, but are not limited to, sulfuric acid (H₂SO₄), hydrochloric acid (HCl), hydrofluoric acid (HF) and nitric acid (HNO₃).

In some embodiments, a ligand (not shown in FIG. 2) may be added to the dissolution solution 245 to assist in the selective dissolution of the titanium halide or titanium oxyhalide passivation layer 225 and/or increase the dissolution rate. A wide variety of ligands may be used in the dissolution solution 245. For example, the ligand may be a complexing agent, a chelating agent or a reducing agent. Examples of ligands that may be used in the dissolution solution 245 include catechol, cupferron and oxalic acid. Other acids and ligands may also be utilized within the dissolution solution 245, as discussed in more detail below.

In order to selectively remove the titanium halide or titanium oxyhalide passivation layer 225, the titanium halide or titanium oxyhalide passivation layer 225 must be soluble, and the unmodified TiN layer 205 underlying the titanium halide or titanium oxyhalide passivation layer 225 must be insoluble, in the dissolution solution 245. The solubility of the titanium halide or titanium oxyhalide passivation layer 225 allows its removal through dissolution into the bulk dissolution solution 245. In some embodiments, the dissolution step 240 may continue until the titanium halide or titanium oxyhalide passivation layer 225 is dissolved.

Once the titanium halide or titanium oxyhalide passivation layer 225 is dissolved within the dissolution solution 245, the wet ALE etch cycle shown in FIG. 2 may be completed by performing a second purge step 250 to remove the dissolution solution 245 from the surface of the substrate. In the second purge step 250, the substrate is rinsed with a second purge solution 255, which may be the same or different than the first purge solution 235. In some embodiments, the second purge solution 255 may use the same solvent (e.g., ethyl acetate or acetone) used within the surface modification solution 215. However, other solvents may also be utilized, as discussed in more detail below. The second purge step 250 may generally continue until the dissolution solution 245 and/or the reactants and soluble species contained with the dissolution solution 245 are completely removed from the surface of the substrate.

Wet ALE of titanium nitride (TiN) requires the formation of a self-limiting passivation layer on the underlying unmodified TiN layer. This passivation layer must be insoluble in the first etch solution used for its formation (i.e., surface modification solution 215), but freely soluble in a second etch solution (i.e., dissolution solution 245) used for its dissolution. The self-limiting passivation layer must be removed every cycle after its formation. The second etch solution is used to selectively dissolve the passivation layer without etching the underlying unmodified TiN layer.

The wet ALE process shown in FIG. 2 may utilize a wide variety of etch chemistries to halogenate and/or oxidize the TiN surface and form a self-limiting, titanium halide or titanium oxyhalide passivation layer in the surface modification step 200. For example, the electrophilic halogenation agent 220 used in the wet ALE process may be an electrophilic chlorinating agent, an electrophilic fluorinating agent or an electrophilic brominating agent.

Examples of electrophilic chlorinating agents that may be included within the surface modification solution 215 include, but are not limited to, trichloroisocyanuric acid (TCCA), thionyl chloride, sulfuryl chloride, N-chlorosuccinimide, 1-chlorobenzotriazole, Chloramine-T and tert-butyl-N-chlorocyanamide. Examples of electrophilic fluorinating agents that may be included within the surface modification solution 215 include, but are not limited to, 1-chloromethyl-4-fluoro-1,4-diazoniabicyclo[2.2.2]octane bis(tetrafluoroborate) (tradename Selectfluor™), 1-fluoropyridinium triflate, 1-fluoro-2,4,6-trimethylpyridinium tetrafluoroborate, N-fluorobenzenesulfonimide, fluoroxytrifluoromethane, perchloryl fluoride, xenon difluoride and N-fluorobis[(trifluoromethyl)sulfonyl]imide. Examples of electrophilic brominating agents that may be included within the surface modification solution 215 include, but are not limited to, N-bromosuccinimide, dibromoisocyanuric acid, tribromocyanuric acid, 1,3-Dibromo-5,5-Dimethylhydantoin and N-Bromoacetamide.

In some embodiments, the electrophilic halogenation agent 220 may be dissolved in a non-aqueous solvent such as an ether, a ketone, a halocarbon, a heterocyclic, an alcohol or another polar organic solvent or chlorocarbon solvent. Examples of non-aqueous solvents include, but are not limited to, ethyl acetate (EA, C₄H₈O₂), acetone (C₃H₆O), acetonitrile (C₂H₃N), dimethyl sulfoxide (DMSO, C₂H₆OS), furan (C₄H₄O), dimethylformamide (C₃H₇NO), methanol (CH₃OH), diethyl ether ((C₂H₅)₂O), isopropyl alcohol (IPA, C₃H₈O), dioxane (C₄H₈O₂) and toluene (C₆H₅CH₃).

In some embodiments, the surface modification solution 215 may be an anhydrous solution comprising an electrophilic chlorinating agent dissolved in non-aqueous solvent. The chlorinating agents listed above are all examples of electrophilic chlorinating agents. In one example, the surface modification solution 215 may comprise trichloroisocyanuric acid (TCCA) dissolved in ethyl acetate (C₄H₈O₂) or acetone (C₃H₆O). When an electrophilic chlorinating agent is used in the surface modification step 200, the electrophilic chlorinating agent included within the surface modification solution 215 may react with the exposed TiN surface to form a titanium chloride (TiClₓ) or titanium oxychloride (TiOCl₂) passivation layer, which is self-limiting and insoluble in the non-aqueous solvent used in the surface modification solution 215.

In some embodiments, the concentration of the electrophilic chlorinating agent may be selected to adjust the etch rate of the TiN layer 205 while preserving post-etch surface roughness. When TCCA is used, the concentration of TCCA used in the surface modification solution 215 may range between 0.1% and 10% with higher TCCA concentration levels providing faster etch rates. In some embodiments, the concentration of TCCA used in the surface modification solution 215 may range between 2% and 5%. Within this concentration range, the post-etch surface roughness is preserved and may even be improved.

In some embodiments, the surface modification step 200 may be performed at (or near) room temperature (e.g., approximately 20-24° C.). In other embodiments, the etch rate of the TiN layer 205 may be increased by increasing the temperature of the surface modification solution 215 above room temperature. In one example, the temperature of the surface modification solution 215 may be increased to a temperature ranging, for example, between 25° C. and 100° C. to increase the etch rate of the TiN layer 205. Increasing the temperature of the surface modification solution 215 increases the etch rate of the TiN layer 205 by increasing the chlorination rate of the exposed TiN surface and/or the thickness of the titanium halide or titanium oxyhalide passivation layer 225 formed thereon. However, the temperature of the surface modification solution 215 may generally depend on the non-aqueous solvent used in the surface modification solution 215. For example, the surface of the substrate may be exposed to the surface modification solution 215 at an elevated temperature ranging between 25° C. and 65° C. when ethyl acetate is used in the surface modification solution 215. In some embodiments, the temperature of the surface modification solution 215 may include the entire liquid range of the non-aqueous solvent used. For example, the temperature of the surface modification solution 215 may range between approximately: (a) −83° C. to 77° C. for ethyl acetate, (b) −95° C. to 56° C. for acetone, (c) 19° C. to 189° C. for DMSO, etc.

After forming a self-limiting titanium halide or titanium oxyhalide passivation layer 225 using one of the halogenating chemistries disclosed above, the wet ALE process shown in FIG. 2 may utilize a wide variety of etch chemistries to selectively remove the titanium halide or titanium oxyhalide passivation layer 225 in the dissolution step 240 without etching the unmodified TiN layer 205 underlying the passivation layer or the dielectric material 210. For example, the wet ALE process may use an acidic solution in the dissolution step 240 to selectively remove the titanium halide or titanium oxyhalide passivation layer 225 via reactive dissolution or ligand-assisted reactive dissolution.

In some embodiments, the dissolution solution 245 may be an aqueous or non-aqueous solution containing an acid such as, but not limited to, sulfuric acid (H₂SO₄), hydrochloric acid (HCl), hydrofluoric acid (HF) or nitric acid (HNO₃). The acid included within the dissolution solution 245 reacts with the titanium halide or titanium oxyhalide passivation layer 225 to form soluble species, which are dissolved in the acid. In some embodiments, the temperature of the dissolution solution 245 may be elevated above room temperature to increase the etch rate of the TiN layer 205. For example, the temperature of the dissolution solution 245 may be elevated to a temperature ranging between 25° C. and 100° C. (for aqueous dissolution solutions) to increase the etch rate of the TiN layer 205 by increasing the dissolution rate of the titanium halide or titanium oxyhalide passivation layer 225.

In other embodiments, the dissolution solution 245 may be an acidic solution containing a ligand and an acid. The ligand added to the dissolution solution 245 may be a complexing agent, a chelating agent or a reducing agent. When a complexing agent or chelating agent is used, the ligand added to the dissolution solution 245 may react with and bind to the unmodified TiN layer 205 to change the surface chemistry of the unmodified TiN layer 205. In doing so, the ligand may prevent (or at least inhibit) parasitic oxidation of the unmodified TiN layer 205 by blocking the unmodified TiN surface. In other embodiments, the ligand added to the dissolution solution 245 may be a reducing agent, which inhibits parasitic oxidation of the unmodified TiN surface during the dissolution step 240. As known in the art, a “reducing agent” is a chemical species that reduces another element, molecule or compound by donating an electron to the other element, molecule or compound (i.e., an electron recipient) during an oxidation-reduction reaction. During the reaction, the reducing agent loses an electron to, or absorbs oxygen from, the electron recipient. In doing so, the reducing agent becomes oxidized and the electron recipient becomes reduced (by losing an oxygen).

In some embodiments, the wet ALE process shown in FIG. 2 may prevent (or at least inhibit) parasitic oxidation of the unmodified TiN surface and prevent continuous etching of the TiN layer 205 during the dissolution step 240 by adding a ligand to the dissolution solution 245. Alternatively, a ligand may not be strictly needed in the dissolution solution 245 if small amounts of halogenated material are left on the TiN surface after the dissolution step 240, as such material may prevent (or inhibit) parasitic oxidation similar to ligands. By forming a self-limiting titanium halide or titanium oxyhalide passivation layer 225 during the surface modification step 200 and preventing reoxidation and continuous etching of the TiN layer 205 during the dissolution step 240, the wet ALE process shown in FIG. 2 provides a post-etch surface roughness of the TiN layer 205 that is substantially equal to (or better than) an initial surface roughness of the TiN layer 205 before etching.

A wide variety of ligands may be added to the dissolution solution 245. Examples of ligands that can be added to the dissolution solution 245 include, but are not limited to, catechol (C₆H₆O₂), cupferron (C₆H₉N₃O₂) and oxalic acid (C₂H₂O₄). However, other ligands can also be used to assist in the selective dissolution of the titanium halide or titanium oxyhalide passivation layer 225 and/or prevent continuous etching of the TiN layer 205 during the dissolution step 240. For example, carboxylic acids (such as, e.g., oxalic acid (C₂H₂O₄), formic acid (HCOOH), acetic acid (CH₃COOH), etc.), amine-containing ligands (such as, e.g., cupferron (C₆H₉N₃O₂), ethylenediamine (C₂H₈N₂), ethylenediaminetetraacetic acid (EDTA, C₁₀H₁₆N₂O₈), iminodiacetic acid (C₄H₇NO₄), etc.), ascorbate anion-containing ligands (such as, e.g., ascorbic acid (C₆H₈O₆), sodium ascorbate (C₆H₇NaO₆), calcium ascorbate (C₁₂H₁₄CaO₁₂) or potassium ascorbate (KC₆H₇O₆), etc.) and other molecules that bind to the TiN surface through N, P, O, or S heteroatoms can be used in the dissolution solution 245.

In one example, the dissolution solution 245 may be an acidic solution comprising 0.05 mM to 5 M of sulfuric acid (H₂SO₄). However, other acids and ligands may be used in the dissolution solution 245 to increase the etch rate of the TiN layer 205 and prevent parasitic oxidation of the unmodified TiN surface while preserving (or improving) the post-etch surface roughness.

### EXPERIMENTAL RESULTS

Etching experiments were conducted on 15 mm×15 mm coupons cut from a 300 mm silicon wafer with various thicknesses of TiN deposited by physical vapor deposition (PVD) on one side to investigate the wet ALE process shown in FIG. 2. The etching experiments used to etch an exposed TiN surface included multiple wet ALE cycles, where each cycle includes a dip in a surface modification solution 215 containing an electrophilic halogenation agent (e.g., TCCA) dissolved in non-aqueous solvent (e.g., ethyl acetate, EA), followed by a first rinse step, a dip in a dissolution solution 245 containing an acid (e.g., sulfuric acid, H₂SO₄), and a second rinse step and blow dry. Each wet ALE process was repeated for a number of ALE cycles under different process conditions to investigate the etch rate achieved by the wet ALE process shown in FIG. 2 using various halogenation and dissolution chemistries. Additional etching experiments were conducted to investigate the effect that: (a) halogenation concentration, temperature and time, and (b) dissolution temperature and time have on the TiN etch rate and post-etch surface roughness.

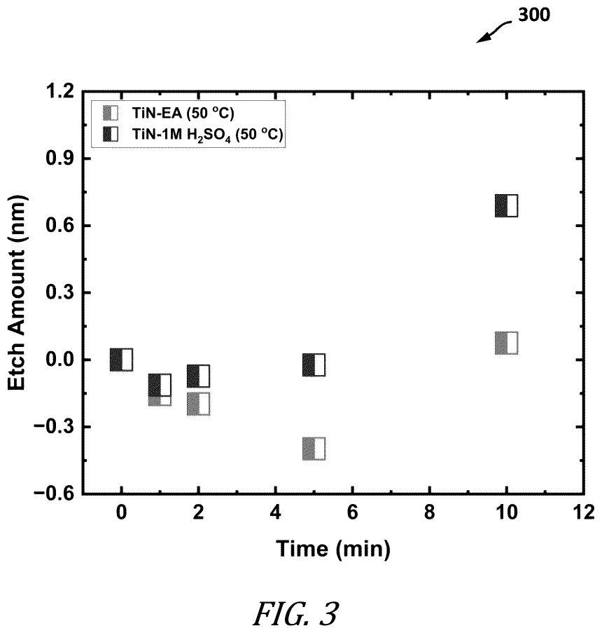

The graph 300 shown in FIG. 3 depicts exemplary etch amounts (expressed in nanometers, nm) achieved over time (expressed in minutes, min) when etching a titanium nitride (TiN) surface using various etch chemistries. To obtain the results shown in the graph 300, a first coupon comprising a PVD-deposited TiN film was exposed to a surface modification solution 215 containing 2% TCCA dissolved in EA for a variable length of time (e.g., 0-10 minutes) to halogenate and/or oxidize the TiN surface and form a titanium halide or titanium oxyhalide passivation layer 225 on the exposed TiN surface. A second coupon comprising a PVD-deposited TiN film was exposed to a dissolution solution 245 containing 1M of sulfuric acid (H₂SO₄) for a variable length of time (e.g., 0-10 minutes) to investigate the background etch of TiN in the acidic dissolution solution. The temperature of the surface modification and dissolution solutions was elevated above room temperature (e.g., to 50° C.). After soaking the coupons in the surface modification and dissolution solutions for X amount of time and performing rinse and blow dry steps, 4-point probe (4pp) resistivity measurements were obtained to measure the etch amount achieved in the two solutions over time.

As shown in the graph 300, the thickness of the TiN film initially increases with soak time up to about 5 minutes in the 2% TCCA-EA surface modification solution, an indication of the formation of a surface product (e.g., a titanium chloride or titanium oxychloride passivation layer) that is different than the starting surface. However, additional chlorination beyond 5 minutes begins to remove material from the TiN surface. This shows that the surface modification step 200 is self-limiting only up to a certain point, after which the self-limiting behavior breaks down with longer soak times. The graph 300 further shows that, while the TiN thickness does not change during the first 5 minutes when dipped in 1M of H₂SO₄, TiN eventually reacts with H₂SO₄ to form an acid-soluble titanium species. This accounts for the continuous etch seen in longer soak times greater than 5 minutes. Accordingly, the graph 300 shown in FIG. 3 indicates that the surface modification and dissolution steps may be self-limiting during shorter soak times (e.g., up to 5 minutes).

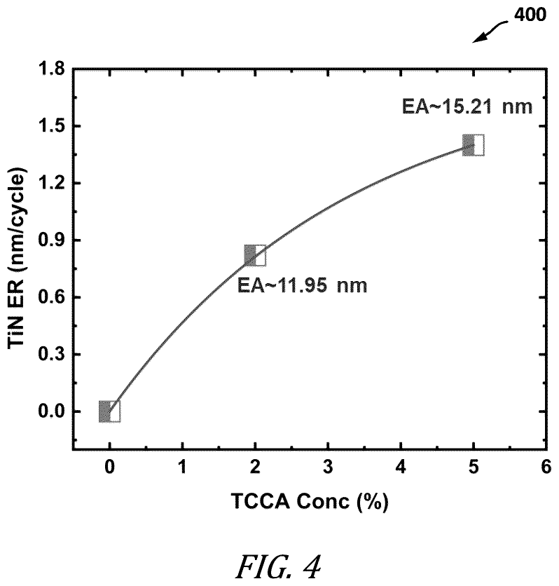

An additional etch experiment was performed to investigate the effect of chlorination concentration on the TiN etch rate. The graph 400 shown in FIG. 4 depicts exemplary etch rates (expressed in nm/cycle) achieved as a function of trichloroisocyanuric acid (TCCA) concentration when using various concentrations (e.g., 2% and 5%) of TCCA dissolved in ethyl acetate to chlorinate and oxidize the TiN surface. The etch recipe used to obtain the results shown in the graph 500 included multiple ALE cycles, where each cycle includes: (a) a 1 minute dip in X% TCCA in ethyl acetate solution at 50° C., (b) an ethyl acetate rinse, (c) a 1 minute dip in 1M of H₂SO₄ solution at 75° C., and (d) an IPA rinse and blow dry. As shown in the graph 400, the etch rate achieved in the different TCCA-ethyl acetate solutions increases with TCCA concentration (˜1.46 nm/cycle for 5% TCCA-EA solution vs. ˜0.84 nm/cycle for 2% TCCA-EA solution), indicating that the chlorination rate and the thickness of the chemically modified TiN layer depends on the TCCA concentration used in the surface modification solution 215.

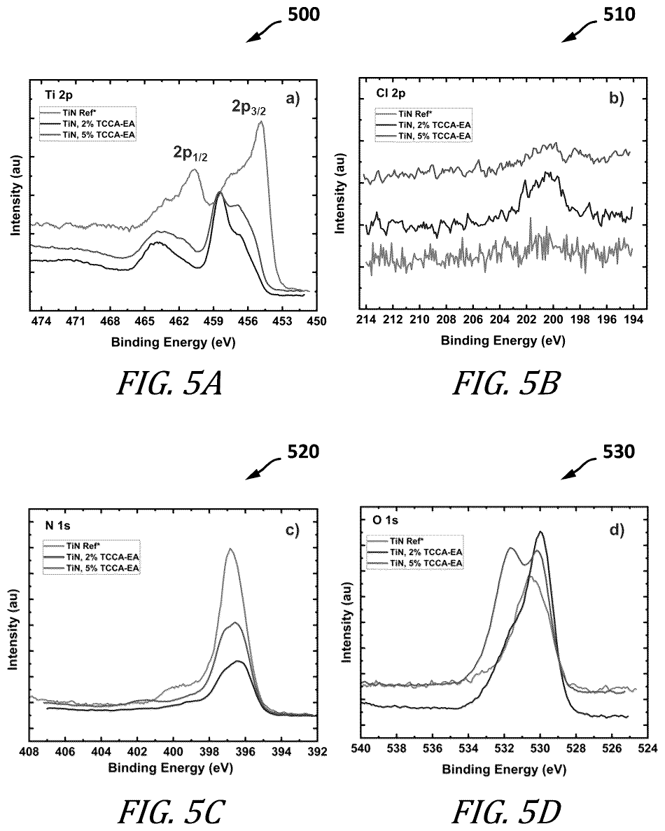

X-ray photoelectron spectroscopy (XPS) analysis was carried out to better understand the surface chemistry of TiN before and after the surface modification step 200. For the reference measurement, the as-deposited TiN surface was cleaned using an argon (Ar) beam at 1 kV to remove any contamination from the surface. Additional TiN coupons were dipped in two different TCCA-EA solutions (e.g., 2% TCCA in EA and 5% TCCA in EA) for 1 minute to chlorinate and oxidate the TiN surface. After rinsing and blow drying the chlorinated coupons, XPS analysis was performed to investigate the surface chemistry of the TiN surface on the reference coupon and the chlorinated coupons. Results of the XPS analysis are shown in FIGS. 5A-5D.

The graph 500 shown in FIG. 5A depicts the XPS spectra for the titanium (Ti) 2p peak before and after exposing the TiN surface to the two different TCCA-EA solutions. It is evident from the graph 500 that Ti³⁺ is the dominant oxidation state in the TiN reference coupon. The existence of a higher binding energy shoulder in the TiN reference coupon also indicates the presence of an oxidized surface layer, such as titanium oxynitride. The Ti 2p peak shifts towards higher binding energy after exposing the TiN coupons to the 2% and 5% TCCA-EA solutions. The sharp Ti 2p peak around 458.6 eV shows surface chlorination shifts the Ti binding energy to a higher Ti⁴⁺ species, likely TiOₓ(OH)₍₄₋₂ₓ₎ given the reactivity of titanium halide compounds towards atmospheric moisture. The existence of a lower binding energy shoulder around 456.8 eV for the 5% TCCA-EA solution and around 456.6 eV for the 2% TCCA-EA solution indicates the presence of incompletely oxidized surface species.

The graph 510 shown in FIG. 5B depicts the XPS spectra of the chlorine (Cl) 2p peak before and after exposing the TiN surface to the two different TCCA-EA solutions. The small signal at around 200 eV indicates the presence of chlorine (Cl) on the TiN surface after exposure to the 2% and 5% TCCA-EA solutions and formation of a titanium chloride (TiClₓ) surface layer on the TiN surface. The modified surface layer is likely titanium tetrachloride (TiCl₄) or titanium oxychloride (TiOCl₂). The Cl binding energy is consistent with Ti—Cl bond formation; however, the low Cl signal intensity is consistent with the high reactivity of Ti—Cl bonds towards water, since titanium chloride (TiClₓ) surface layers will rapidly hydrolyze on exposure to air.

The graph 520 shown in FIG. 5C depicts the XPS spectra of the nitrogen (N) 1s peak before and after exposing the TiN surface to the two different TCCA-EA solutions. The N 1s peak shows that N signal significantly decreases after exposing the TiN surface to the 2% and 5% TCCA-EA solutions. This is consistent with removal of nitrogen from the surface layer. However, the N 1s signal is stronger in the TiN coupon after soaking in the 5% TCCA-EA solution compared to the N 1s signal coming from TiN surface that was dipped in the 2% TCCA-EA solution, indicating greater amounts of nitrogen are removed in the 2% TCCA-EA solution.

The graph 530 shown in FIG. 5D depicts the XPS spectra of the oxygen (O) 1s peak before and after exposing the TiN surface to the two different TCCA-EA solutions. The TiN coupon dipped in the 5% TCCA-EA solution shows a splitting of the O 1s spectra. The O 1s peak at the higher binding energy (˜531.8 eV) is consistent with the presence of a Ti—O—N, Ti—OH or surface hydrates bond, whereas the O 1s peak at the lower binding energy (˜530.2 eV) indicates the presence of titanium oxide (TiO₂). The TiN coupon dipped in the 2% TCCA-EA solution shows an O 1s peak at around 529.9 eV, an indication of presence of TiO₂ on the surface.

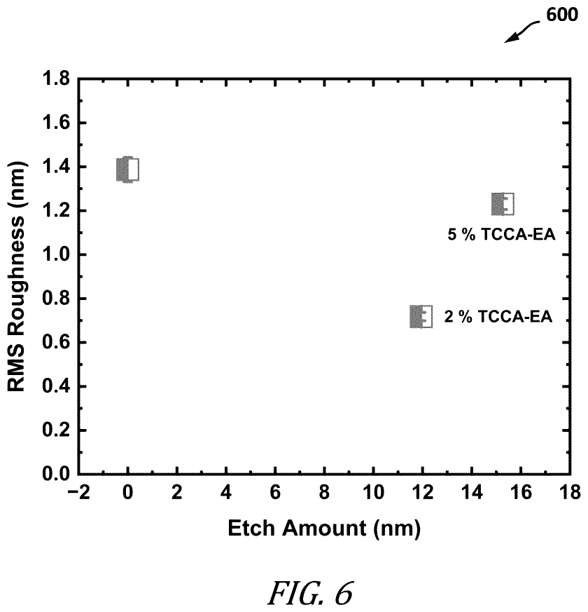

An additional etch experiment was performed to investigate the effect of chlorination concentration on the post-etch surface roughness. The graph 600 shown in FIG. 6 depicts the root mean square (RMS) roughness (expressed in nm) of an as-deposited TiN surface and post-etch TiN surfaces as a function of etch amount (expressed in nm) for the two different TCCA-EA solutions mentioned above (e.g., 2% TCCA in EA and 5% TCCA in EA). The etch recipe used to obtain the results shown in the graph 600 included multiple ALE cycles, where each cycle includes: (a) a 1 minute dip in 2% or 5% TCCA in EA solution at 50° C., (b) an EA rinse, (c) a 1 minute dip in 1M of H₂SO₄ solution at 75° C., and (d) an IPA rinse and blow dry.

As shown in the graph 600, the post-etch morphology of the TiN coupon is preserved irrespective of TCCA concentration. In fact, the graph 600 shows that the surface roughness of the TiN coupon improves after etching with the chlorinating etch chemistry. The improved post-etch morphology is attributed to the formation of a conformal titanium chloride (TiClₓ) surface product that can be selectively removed via reactive dissolution in the sulfuric acid solution. The graph 600 further shows that the RMS roughness (˜(0.72±0.02) nm) of the TiN coupon etched using the 2% TCCA-EA solution is much lower than the RMS roughness (˜(1.39±0.06) nm) of the as-deposited TiN reference coupon and the RMS roughness (˜(1.23±0.03) nm) of the TiN coupon etched using the 5% TCCA-EA solution. This indicates that lower TCCA concentrations may be preferable when post-etch surface roughness and interface resistance are of concern.

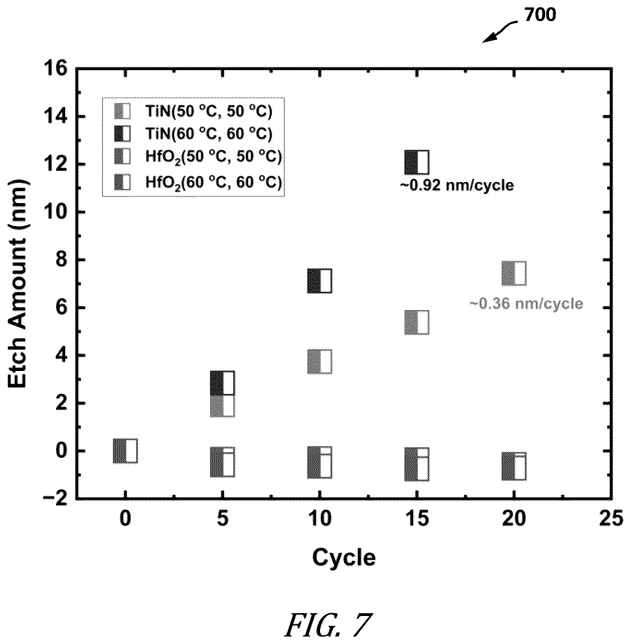

Additional etch experiments were performed to investigate the effect of chlorination temperature on the TiN etch rate and the etch selectivity between TiN and hafnium dioxide (HfO₂). The graph 700 shown in FIG. 7 shows the etch rate (expressed in nm/cycle) achieved when etching TiN and HfO₂ using 2% TCCA dissolved in ethyl acetate in the surface modification solution and 1 M of sulfuric acid (H₂SO₄) in the dissolution solution at different temperatures (e.g., 50° C. and 60° C.). The etch recipe used to obtain the results shown in the graph 700 included multiple ALE cycles, where each cycle includes: (a) a 1 minute dip in 2% TCCA in EA solution at X° C., (b) an EA rinse, (c) a 1 minute dip in 1M of H₂SO₄ solution at X° C., and (d) an IPA rinse and blow dry.

As shown in the graph 700, the TiN etch rate increases within increase in chlorination and reactive dissolution temperature, an indication that the TiN etch rate is driven by solution phase kinetics. Specifically, the TiN etch rate (˜0.92 nm/cycle) after chlorination and dissolution at 60° C. is about 2.5 times higher than the TiN etch rate (˜0.36 nm/cycle) achieved when chlorination and reactive dissolution was performed at 50° C.. Significant improvement in TiN etch rate at 60° C. indicates that the thickness of the modified surface layer is temperature-dependent. The graph 700 further shows that the same etch chemistry cannot be used to remove HfO₂. This may be due, at least in part, to the difficulty in changing the surface chemistry of HfO₂ at or near room temperature. This offers a great etch selectivity between TiN and HfO₂.

As shown in the etching experiments above, the surface modification of TiN is self-limiting in non-aqueous chlorinating solutions (such as, e.g., TCCA-ethyl acetate) and acidic dissolutions up until a certain point (such as, e.g., 5 minutes). Self-limiting behavior during the surface modification step is attributed to the formation of a conformal titanium halide or titanium oxyhalide passivation layer (e.g., a titanium chloride (TiClₓ) or titanium oxychloride (TiO_{y}Cl_{(x-2y)}) passivation layer), which is insoluble in the non-aqueous solvents used in the surface modification solution. The modified TiN surface layer is subsequently removed via reactive dissolution in acidic solution. The etching experiments provided herein further show that the TiN etch rate (ER) can be tuned by changing the TCCA concentration used during the surface modification step and/or the chlorination/dissolution temperature. As shown above, the post etch surface morphology improves independent of TCCA concentration. The preserved surface smoothness in the post-etch TiN coupon can be attributed to the formation of a conformal titanium halide or oxyhalide as a passivation layer that prevents continuous TiN etch. The etch chemistry used herein for etching TiN provides excellent selectivity between TiN and surrounding dielectric materials, such as HfO₂.

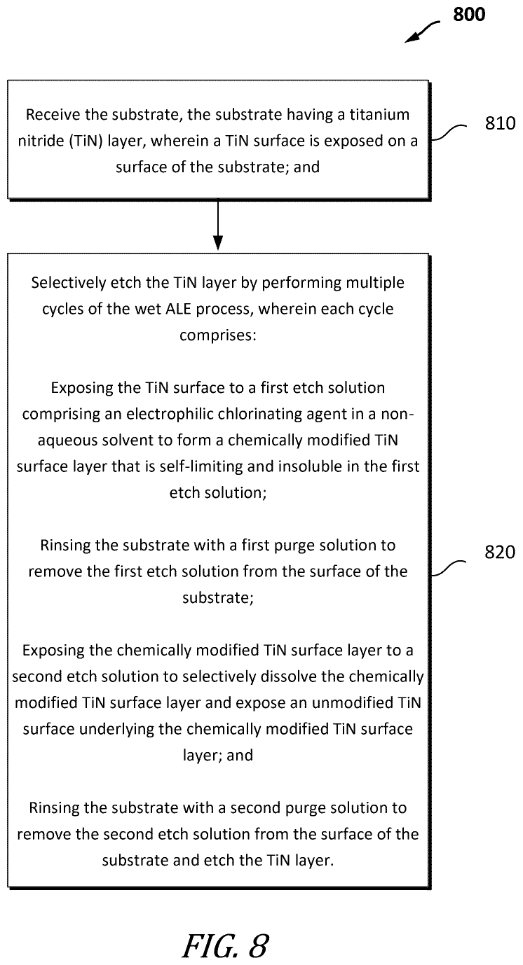

FIG. 8 illustrates another embodiment of a method 800 that can be used for etching a substrate using a wet ALE process. More specifically, FIG. 8 illustrates a method 800 that can be used to etch a substrate having a titanium nitride (TiN) layer using a wet ALE process, which utilizes halogenation to modify a TiN surface and form a self-limiting titanium halide or titanium oxyhalide passivation layer. It will be recognized that the embodiment of FIG. 8 is merely exemplary and additional methods may utilize the wet ALE techniques described herein. Further, additional processing steps may be added to the method shown in the FIG. 8 as the steps described are not intended to be exclusive. Moreover, the order of the steps is not limited to the order shown in the figures as different orders may occur and/or various steps may be performed in combination or at the same time.

The method 800 shown in FIG. 8 begins by receiving the substrate, the substrate having a titanium nitride (TiN) layer, wherein a TiN surface is exposed on a surface of the substrate (in step 810). Then, in step 820, the method 800 includes selectively etching the TiN layer by performing multiple cycles of the wet ALE process, wherein each cycle comprises: (a) exposing the TiN surface to a first etch solution comprising an electrophilic chlorinating agent dissolved in a non-aqueous solvent to form a chemically modified TiN surface layer that is self-limiting and insoluble in the non-aqueous solvent; (b) rinsing the substrate with a first purge solution to remove the first etch solution from the surface of the substrate; (c) exposing the chemically modified TiN surface layer to a second etch solution to selectively dissolve the chemically modified TiN surface layer and expose an unmodified TiN surface underlying the chemically modified TiN surface layer; and (d) rinsing the substrate with a second purge solution to remove the second etch solution from the surface of the substrate and etch the TiN layer.

In the method 800, the electrophilic chlorinating agent reacts with the TiN surface to form a titanium chloride or titanium oxychloride passivation layer, which is self-limiting and insoluble in the non-aqueous solvent. In some embodiments, a concentration of the electrophilic chlorination agent in the first etch solution may be selected to adjust an etch rate of the TiN layer without substantially increasing a post-etch surface roughness of the TiN layer compared to an initial surface roughness of the TiN layer before etching.

A wide variety of electrophilic chlorinating agents and non-aqueous solvents may be utilized in the first etch solution, as described above. In some embodiments, the electrophilic chlorinating agent may be trichloroisocyanuric acid (TCCA) and the non-aqueous solvent may be a polar organic solvent. In some embodiments, the TCCA concentration in the first etch solution may range between 0.1 and 10%, or more specifically, between 2% and 5%. In one example embodiment, the first etch solution may comprise 2% TCCA dissolved in ethyl acetate or acetone.

In some embodiments, the second etch solution may comprise an acid. The titanium chloride or titanium oxychloride passivation layer may selectively dissolved by the acid included within the second etch solution to expose the unmodified TiN surface underlying the titanium chloride or titanium oxychloride passivation layer. In some embodiments, the second etch solution may further comprise a ligand to assist in the selective dissolution of the titanium chloride or titanium oxychloride passivation layer and/or increase the dissolution rate.

A wide variety of acids and ligands may be utilized in the second etch solution, as described above. For example, the acid may be sulfuric acid (H₂SO₄), hydrochloric acid (HCl), hydrofluoric acid (HF) or nitric acid (HNO₃), and the ligand may be oxalic acid, formic acid, acetic acid, cupferron, ethylenediamine, ethylenediaminetetraacetic acid (EDTA), iminodiacetic acid, catechol, ascorbic acid, sodium ascorbate, calcium ascorbate or potassium ascorbate. In one example embodiment, the second etch solution may include 0.05 mM to 5 M of sulfuric acid (H₂SO₄).

The methods and wet ALE processes described above and shown in FIGS. 1, 2 and 8 for etching TiN can be accomplished using a variety of techniques. For example, the TiN wet ALE processes disclosed above may be performed by dipping the TiN sample in beakers of each etch solution. In this case, purging can be accomplished by either rinsing or dipping the sample in an appropriate solvent bath. The TiN wet ALE processes can also be accomplished on a spinner. For example, the TiN sample may be rotated while the etchant solutions are dispensed from a nozzle positioned above the sample. The rotational motion of the sample distributes the solution over the surface. After the set exposure time, the nozzle begins dispensing the next solution in the etch recipe. This process continues through the whole etch cycle and repeats for as many cycles as necessary to remove the desired amount of TiN. For high volume manufacturing, dispensing of etch solutions and rinses can be executed using conventional tools, such as wet etching tools and rinse tools.

Example process conditions (e.g., etch chemistry, temperature, processing time, etc.) are provided herein for etching transition metal nitride materials, and more specifically, for etching titanium nitride (TiN) using the methods and wet ALE processes described above and shown in FIGS. 1, 2 and 8. It will be recognized by those skilled in the art, however, that the methods and wet ALE processes disclosed herein are not strictly limited to the example process conditions described herein and may be performed using a wide variety of process conditions depending on the material being etched.

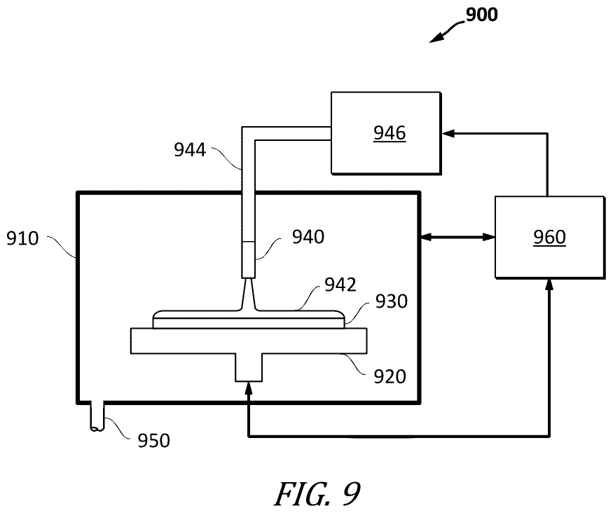

FIG. 9 illustrates one embodiment of a processing system 900 that can etch a transition metal nitride surface, such as a TiN surface, on a surface of a substrate 930 using the wet ALE processes disclosed herein. As shown in FIG. 9, the processing system 900 includes a process chamber 910, which in some embodiments, may be a pressure controlled chamber. In the embodiment shown in FIG. 9, the process chamber 910 is a spin chamber having a spinner 920 (or spin chuck), which is configured to spin or rotate at a rotational speed. A substrate 930 is held on the spinner 920, for example, via electrostatic force or vacuum pressure. In one example, the substrate 930 may be a semiconductor wafer having a transition metal nitride material, such as TiN, formed on or within the substrate 930.

The processing system 900 shown in FIG. 9 further includes a liquid nozzle 940, which is positioned over the substrate 930 for dispensing various etch solutions 942 onto a surface of the substrate 930. The etch solutions 942 dispensed onto the surface of the substrate 930 may generally include a surface modification solution to chemically modify the TiN surface and form a modified surface layer (e.g., a titanium chloride or titanium oxychloride passivation layer), and a dissolution solution to selectively remove the modified surface layer from the TiN surface. Purge solutions may also be dispensed onto the surface of the substrate 930 between surface modification and dissolution steps to separate the surface modification and dissolution solutions. Examples of surface modification, dissolution and purge solutions are discussed above.

As shown in FIG. 9, the etch solutions 942 may be stored within a chemical supply system 946, which may include one or more reservoirs for holding the various etch solutions 942 and a chemical injection manifold, which is fluidly coupled to the process chamber 910 via a liquid supply line 944. In operation, the chemical supply system 946 may selectively apply desired chemicals to the process chamber 910 via the liquid supply line 944 and the liquid nozzle 940 positioned within the process chamber 910. Thus, the chemical supply system 946 can be used to dispense the etch solutions 942 onto the surface of the substrate 930. The process chamber 910 may further include a drain 950 for removing the etch solutions 942 from the process chamber 910.

Components of the processing system 900 can be coupled to, and controlled by, a controller 960, which in turn, can be coupled to a corresponding memory storage unit and user interface (not shown). Various processing operations can be executed via the user interface, and various processing recipes and operations can be stored in the memory storage unit. Accordingly, a given substrate 930 can be processed within the process chamber 910 in accordance with a particular recipe. In some embodiments, a given substrate 930 can be processed within the process chamber 910 in accordance with an etch recipe that utilizes the wet ALE techniques described herein for etching TiN and other transition metal nitrides.

The controller 960 shown in block diagram form in FIG. 9 can be implemented in a wide variety of manners. In one example, the controller 960 may be a computer. In another example, the controller 960 may include one or more programmable integrated circuits that are programmed to provide the functionality described herein. For example, one or more processors (e.g., microprocessor, microcontroller, central processing unit, etc.), programmable logic devices (e.g., complex programmable logic device (CPLD), field programmable gate array (FPGA), etc.), and/or other programmable integrated circuits can be programmed with software or other programming instructions to implement the functionality of a prescribed process recipe. It is further noted that the software or other programming instructions can be stored in one or more non-transitory computer-readable mediums (e.g., memory storage devices, flash memory, dynamic random access memory (DRAM), reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

As shown in FIG. 9, the controller 960 may be coupled to various components of the processing system 900 to receive inputs from, and provide outputs to, the components. For example, the controller 960 may be coupled to: the process chamber 910 for controlling the temperature and/or pressure within the process chamber 910; the spinner 920 for controlling the rotational speed of the spinner 920; and the chemical supply system 946 for controlling the various etch solutions 942 dispensed onto the substrate 930. The controller 960 may control other processing system components not shown in FIG. 9, as is known in the art.

In some embodiments, the controller 960 may control the various components of the processing system 900 in accordance with an etch recipe that utilizes the wet ALE techniques described herein for etching a titanium nitride (TiN) layer. For example, the controller 960 may supply various control signals to the chemical supply system 946, which cause the chemical supply system 946 to: a) dispense a surface modification solution onto the surface of the substrate 930 to chemically modify exposed surfaces of the TiN layer and create a chemically modified TiN surface layer (e.g., a titanium chloride or titanium oxychloride passivation layer) on the substrate 930; b) rinse the substrate 930 with a first purge solution to remove the surface modification solution and excess reactants from the surface; c) dispense a dissolution solution onto the surface of the substrate 930 to selectively remove or dissolve the chemically modified TiN surface layer; and d) rinse the substrate with a second purge solution to remove the dissolution solution from the surface of the substrate 930. In some embodiments, the controller 960 may supply the control signals to the chemical supply system 946 in a cyclic manner, such that the steps a)-d) are repeated for one or more ALE cycles, until a desired amount of the TiN layer has been removed.

The controller 960 may also supply control signals to other processing system components. In some embodiments, for example, the controller 960 may supply control signals to the spinner 920 and/or the chemical supply system 946 to dry the substrate 930 after the second purge step is performed. In one example, the controller 960 may control the rotational speed of the spinner 920, so as to dry the substrate 930 in a spin dry step. In another example, control signals supplied from the controller 960 to the chemical supply system 946 may cause a drying agent (such as, e.g., isopropyl alcohol) to be dispensed onto the surface of the substrate 930 to further assist in drying the substrate before performing the spin dry step.

In some embodiments, the controller 960 may control the temperature and/or the pressure within the process chamber 910. In some embodiments, the surface modification, dissolution and purge steps of the wet ALE processes described herein may be performed at roughly the same temperature and pressure. In one example implementation, the surface modification, dissolution and purge steps may each be performed at (or near) atmospheric pressure and room temperature. Performing the processing steps within the same process chamber at roughly the same temperature and pressure decreases the cycle time and improves the throughput of the wet ALE process described herein by avoiding unnecessary chamber transitions and temperature/pressure changes.

It is noted, however, that the embodiments described herein are not strictly limited to only atmospheric pressure and room temperature, nor are they limited to a particular process chamber. In other embodiments, one or more of the surface modification, dissolution and purge steps can be run at above atmospheric pressure in a pressure vessel, or at reduced pressure in a vacuum chamber. Etch solutions can be dispensed in these environments as long as the vapor pressure of the liquid is lower than the chamber pressure. For these implementations, a spinner with a liquid dispensing nozzle would be placed in the pressure vessel or vacuum chamber. The temperature of the liquid being dispensed can be elevated to any temperature below its boiling point at the pressure of the process. In one example implementation, the surface modification and dissolution steps may be performed at an elevated temperature (for example, at about 60° C.) to increase the chlorination and dissolution rates and increase the TiN etch rate.

The present disclosure provides systems and methods that utilize new etch chemistries for etching titanium nitride (TiN) in a wet ALE process. As described above, the wet ALE processes and methods disclosed herein use a wide variety of techniques and etch chemistries to halogenate and/or oxidize a TiN layer exposed on a surface of a substrate and form a self-limiting, titanium halide or titanium oxyhalide passivation layer in a surface modification step of the wet ALE process. After forming the titanium halide or titanium oxyhalide passivation layer, reactive dissolution in acidic solution is used in the dissolution step of the wet ALE process to provide self-limited, selective dissolution of the passivation layer without increasing the post-etch surface roughness. In some embodiments, the TiN etch rate is improved by increasing the concentration of the halogenation agent used in the surface modification solution and/or by increasing the temperature of the surface modification and dissolution solutions, while preserving or even improving surface roughness.

Although described herein for etching titanium nitride (TiN), the techniques described herein may be used for etching other transition metal nitride materials such as, for example, molybdenum nitride (MoN), tantalum nitride (TaN), chromium nitride (CrN), aluminum nitride (AlN), hafnium nitride (HfN), zirconium nitride (ZrN) and iron nitride (FeₓN). However, the techniques described herein may not be sufficient to modify surrounding dielectric surfaces, such as zirconium dioxide (ZrO₂), hafnium dioxide (HfO₂) or hafnium zirconium dioxide (HfₓZr₍₁₋ₓ₎O₂) dielectrics, due to the etch chemistry used during the surface modification step (e.g., TCCA) and/or the difficulty in changing the surface chemistry of such materials at or near room temperature. Thus, the etch chemistries and methods disclosed herein for etching TiN may provide good etch selectivity to such materials.

U.S. Pat. No. 11,802,342, entitled “Methods for Wet Atomic Layer Etching of Ruthenium,” describes a similar wet ALE process that uses surface modification solution containing a halogenating agent (such as, e.g., TCCA) dissolved in non-aqueous solvent to form a self-limiting, ruthenium halide or ruthenium oxyhalide passivation layer on an exposed ruthenium (Ru) surface, and a dissolution solution containing a strong base (such as, e.g., KOH) to selectively dissolve the ruthenium halide or ruthenium oxyhalide passivation layer. Such an etch chemistry cannot be used to etch TiN. If the titanium halide or titanium oxyhalide passivation layer formed during the surface modification step disclosed herein were exposed to a base (such as KOH), instead of an acid, the reaction between the modified TiN layer and the base would most likely lead to the formation of an insoluble titanium hydroxide surface product, which would prevent the modified TiN layer from being removed in the dissolution step.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method of etching, the method comprising:
receiving a substrate having a titanium nitride (TiN) layer, wherein a TiN surface is exposed on a surface of the substrate;
exposing the surface of the substrate to a surface modification solution comprising an electrophilic halogenation agent dissolved in a non-aqueous solvent, wherein the electrophilic halogenation agent reacts with the TiN surface to form a titanium halide or titanium oxyhalide passivation layer, which is self-limiting and insoluble in the surface modification solution;
removing the surface modification solution from the surface of the substrate subsequent to forming the titanium halide or titanium oxyhalide passivation layer;
exposing the surface of the substrate to a dissolution solution to selectively remove the titanium halide or titanium oxyhalide passivation layer, wherein the dissolution solution reacts with the titanium halide or titanium oxyhalide passivation layer to form soluble species, which are dissolved by the dissolution solution to expose an unmodified TiN surface underlying the titanium halide or titanium oxyhalide passivation layer; and
removing the dissolution solution and the soluble species from the surface of the substrate to etch the TiN layer.

2. The method of claim 1, further comprising repeating said exposing the surface of the substrate to the surface modification solution, removing the surface modification solution, exposing the surface of the substrate to the dissolution solution, and removing the dissolution solution and the soluble species a number of times until a predetermined amount of the TiN layer is removed from the substrate.

3. The method of claim 1, wherein the electrophilic halogenation agent is an electrophilic chlorinating agent, an electrophilic fluorinating agent or an electrophilic brominating agent.

4. The method of claim 3, wherein the electrophilic chlorinating agent is trichloroisocyanuric acid (TCCA), thionyl chloride, sulfuryl chloride, N-chlorosuccinimide, 1-chlorobenzotriazole, Chloramine-T and tert-butyl-N-chlorocyanamide.

5. The method of claim 3, wherein the non-aqueous solvent is an ether, a ketone, a halocarbon, a heterocyclic, an alcohol or another polar organic solvent or chlorocarbon solvent.

6. The method of claim 1, wherein the surface modification solution is a non-aqueous solution comprising an electrophilic chlorinating agent dissolved in the non-aqueous solvent, wherein the electrophilic chlorinating agent reacts with the TiN surface to form a titanium chloride or titanium oxychloride passivation layer, which is self-limiting and insoluble in the surface modification solution.

7. The method of claim 6, wherein prior to exposing the surface of the substrate to the surface modification solution, the method further comprises selecting a concentration of the electrophilic chlorinating agent in the surface modification solution to adjust an etch rate of the TiN layer without increasing a post-etch surface roughness of the TiN layer compared to an initial surface roughness of the TiN layer before etching.

8. The method of claim 6, wherein the surface modification solution comprises trichloroisocyanuric acid (TCCA) dissolved in a polar organic solvent, and wherein a concentration of the TCCA in the surface modification solution ranges between 0.1% and 10%.

9. The method of claim 6, wherein the surface modification solution comprises 2% to 5% trichloroisocyanuric acid (TCCA) dissolved in ethyl acetate or acetone.

10. The method of claim 6, wherein said exposing the surface of the substrate to the surface modification solution comprises:
exposing the surface of the substrate to the surface modification solution at an elevated temperature ranging between 25° C. and 100° C., wherein the elevated temperature increases an etch rate of the TiN layer by increasing a chlorination rate of the TiN surface.

11. The method of claim 6, wherein the dissolution solution comprises an acid, which reacts with the titanium chloride or titanium oxychloride passivation layer to form the soluble species, which are dissolved by the dissolution solution to expose the unmodified TiN surface underlying the titanium chloride or titanium oxychloride passivation layer.

12. The method of claim 11, wherein said exposing the surface of the substrate to the dissolution solution comprises:
exposing the surface of the substrate to the dissolution solution at an elevated temperature ranging between 25° C. and 100° C., wherein the elevated temperature increases an etch rate of the TiN layer by increasing a dissolution rate of the titanium chloride or titanium oxychloride passivation layer.

13. The method of claim 11, wherein the acid is sulfuric acid (H₂SO₄), hydrochloric acid (HCl), hydrofluoric acid (HF) or nitric acid (HNO₃).

14. The method of claim 11, wherein the dissolution solution further comprises a ligand, which assists in the selective removal of the titanium chloride or titanium oxychloride passivation layer and/or increases a dissolution rate of the titanium chloride or titanium oxychloride passivation layer.

15. The method of claim 14, wherein the ligand is oxalic acid, formic acid, acetic acid, cupferron, ethylenediamine, ethylenediaminetetraacetic acid (EDTA), iminodiacetic acid, catechol, ascorbic acid, sodium ascorbate, calcium ascorbate or potassium ascorbate.

16. The method of claim 14, wherein the dissolution solution comprises 0.05 mM to 5 M of sulfuric acid (H₂SO₄).

17. A method of etching a substrate using a wet atomic layer etching (ALE) process, the method comprising:
receiving the substrate, the substrate having a titanium nitride (TiN) layer, wherein a TiN surface is exposed on a surface of the substrate; and
selectively etching the TiN layer by performing multiple cycles of the wet ALE process, wherein each cycle comprises:
exposing the TiN surface to a first etch solution comprising an electrophilic chlorinating agent dissolved in a non-aqueous solvent to form a chemically modified TiN surface layer that is self-limiting and insoluble in the non-aqueous solvent;
rinsing the substrate with a first purge solution to remove the first etch solution from the surface of the substrate;
exposing the chemically modified TiN surface layer to a second etch solution to selectively dissolve the chemically modified TiN surface layer and expose an unmodified TiN surface underlying the chemically modified TiN surface layer; and
rinsing the substrate with a second purge solution to remove the second etch solution from the surface of the substrate and etch the TiN layer.

18. The method of claim 17, wherein the electrophilic chlorinating agent reacts with the TiN surface to form a titanium chloride or titanium oxychloride passivation layer, which is self-limiting and insoluble in the non-aqueous solvent, and wherein a concentration of the electrophilic chlorination agent in the first etch solution is selected to adjust an etch rate of the TiN layer without increasing a post-etch surface roughness of the TiN layer compared to an initial surface roughness of the TiN layer before etching.

19. The method of claim 18, wherein the first etch solution comprises trichloroisocyanuric acid (TCCA) dissolved in a polar organic solvent, and wherein a concentration of the TCCA in the first etch solution ranges between 0.1% and 10%.

20. The method of claim 18, wherein the first etch solution comprises 2% to 5% trichloroisocyanuric acid (TCCA) dissolved in ethyl acetate or acetone.

21. The method of claim 18, wherein the second etch solution comprises an acid, wherein the titanium chloride or titanium oxychloride passivation layer is selectively dissolved by the acid to expose the unmodified TiN surface underlying the titanium chloride or titanium oxychloride passivation layer.

22. The method of claim 21, wherein the second etch solution further comprises a ligand, which assists in the selective dissolution of the titanium chloride or titanium oxychloride passivation layer and/or increases a dissolution rate of the titanium chloride or titanium oxychloride passivation layer.

23. The method of claim 21, wherein the second etch solution comprises 0.05 mM to 5 M of sulfuric acid (H₂SO₄).

24. The method of claim 17, wherein the substrate further comprises an oxide layer, wherein an oxide surface of the oxide layer is exposed on the surface of the substrate, and wherein said selectively etching the TiN layer is selective to the oxide layer.

25. The method of claim 24, wherein the oxide layer comprises zirconium dioxide (ZrO₂), hafnium dioxide (HfO₂) or hafnium zirconium dioxide (HfₓZr₍₁₋ₓ₎O₂).
